(19) United States
(12) Patent Application Publication
(10) Pub. No.: US 2026/0179680 A1
(43) Pub. Date: Jun. 25, 2026

(54) READ PATH BIT-LINE PRECHARGE ARCHITECTURE FOR MULTI-VOLTAGE RAM

(71) Applicant: NVIDIA Corporation, Santa Clara, CA (US)

(72) Inventors: Lalit Gupta, Freemont, CA (US); Cagri Erbagci, Pittsburgh, PA (US)

(21) Appl. No.: 19/000,218

(22) Filed: Dec. 23, 2024

(51) Int. Cl. G11C 11/419

(52) U.S. Cl. CPC G11C 11/419

(57) ABSTRACT

An electrical device including a memory circuit and a general input output circuit. The memory circuit includes bit-cell circuits, each bit-cell circuit including a memory cell and a read port. The memory cell is electrically connected to a read word line at a read output voltage and is electrically connected to the read port by the read word line. The read port is further connected to a read bit-line complement signal at a write output logic voltage or at a read bit-line complement output voltage that is less than or equal to the write output logic voltage. The general input output circuit includes a bit-line pre-charge control circuit and a voltage level shifter circuit, wherein the read bit-line complement signal is connected to the bit-line pre-charge control circuit and to the voltage level shifter circuit.

### TECHNICAL FIELD

This application is directed, in general, to memory circuits and more specifically integrated circuits including multi-voltage random access memory (RAM).

### BACKGROUND

Integrated circuits (ICs) that include memory circuits, such as random-access memory (RAM) circuit that include memory cell or bit-cell circuits, can have a read bit-line conductive path that is operated on by supply voltages with different voltage levels. Voltage level shifting using voltage level shifter circuits as part of such multi-voltage powered RAM bit-cells can offer advantages by eliminating the need for separate voltage level shifters.

### SUMMARY

One aspect provides an electrical device including a memory circuit and a general input output circuit. The memory circuit includes bit-cell circuits, each bit-cell circuit including a memory cell and a read port). The memory cell is electrically connected to a read word line at a read output voltage and is electrically connected to the read port by the read word line. The read port is further connected to a read bit-line complement signal at a write output logic voltage or at a read bit-line complement output voltage that is less than or equal to the write output logic voltage. The general input output circuit including a bit-line pre-charge control circuit and a voltage level shifter circuit, wherein the read bit-line complement signal is connected to the bit-line pre-charge control circuit and to the voltage level shifter circuit.

### BRIEF DESCRIPTION

Reference is now made to the following descriptions taken in conjunction with the accompanying drawings, in which:

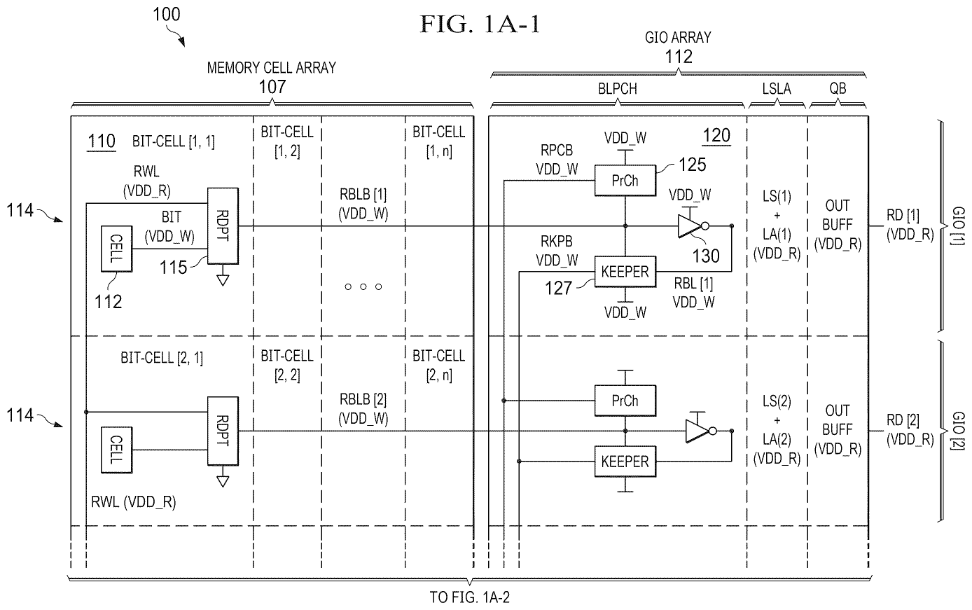

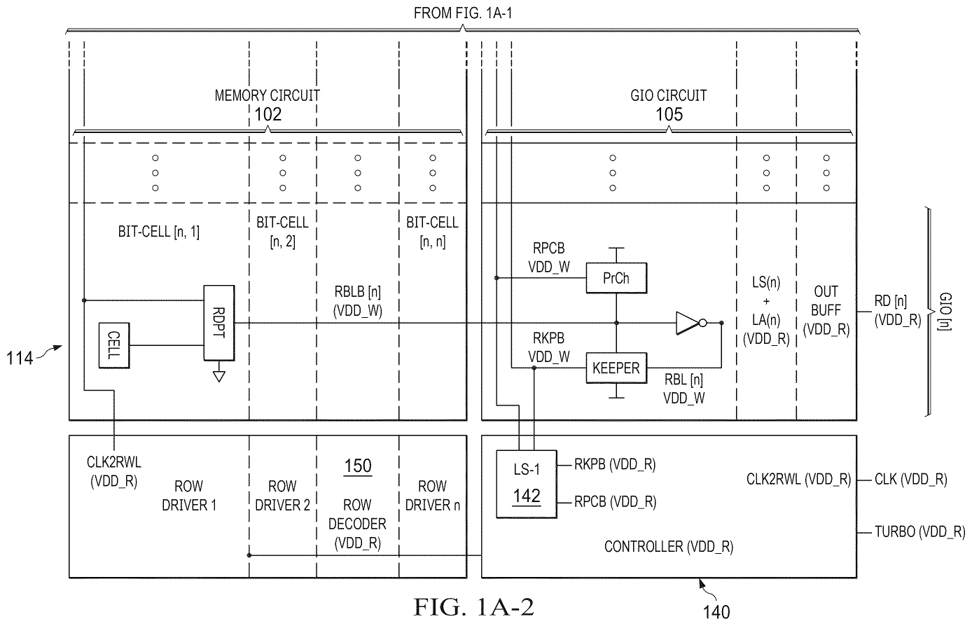

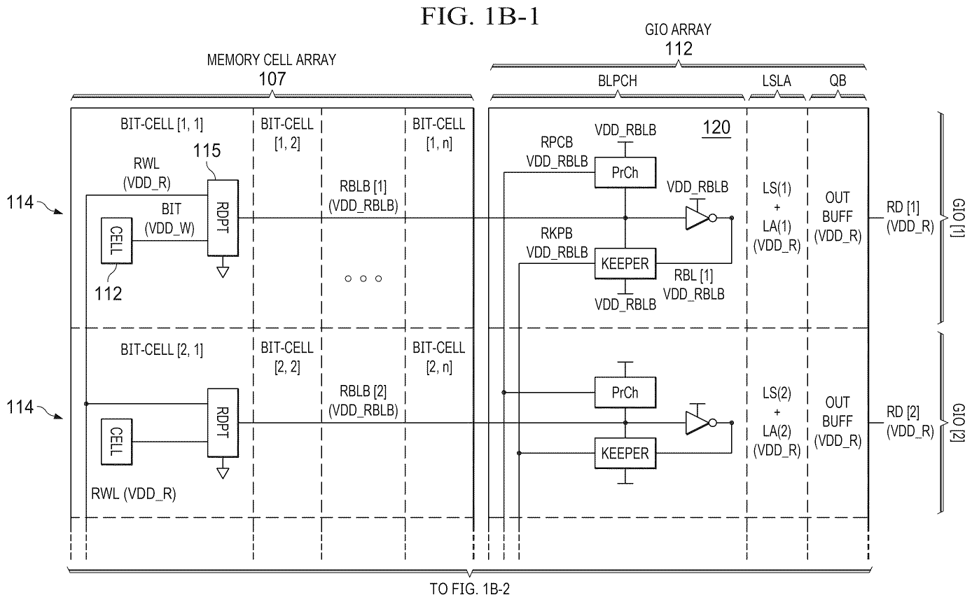

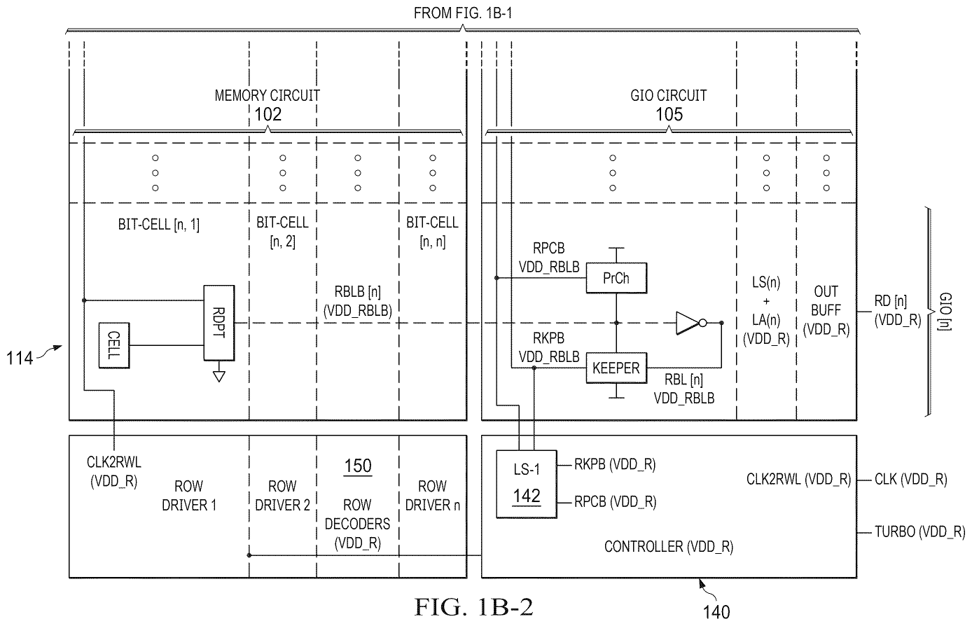

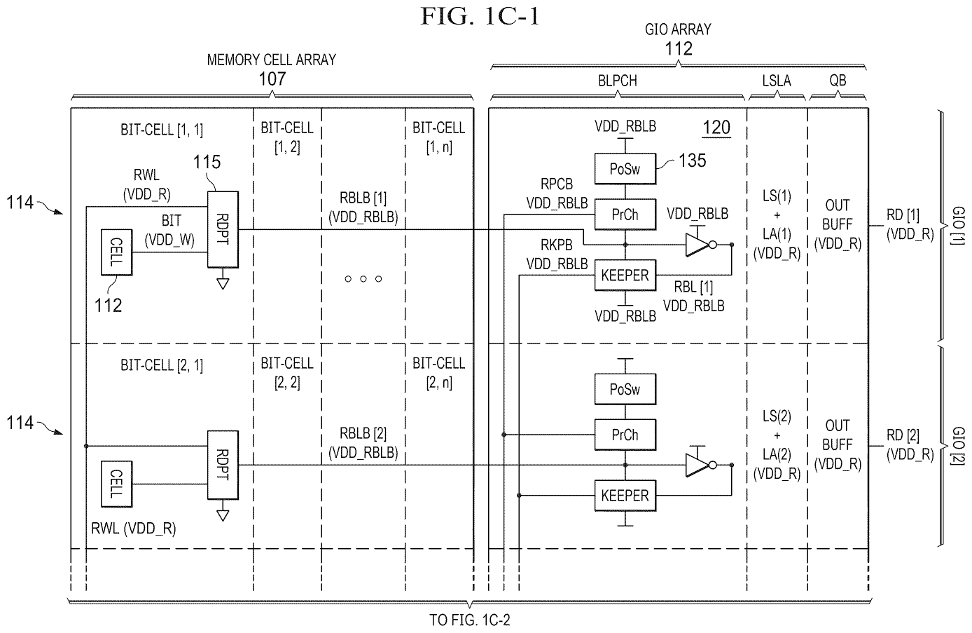

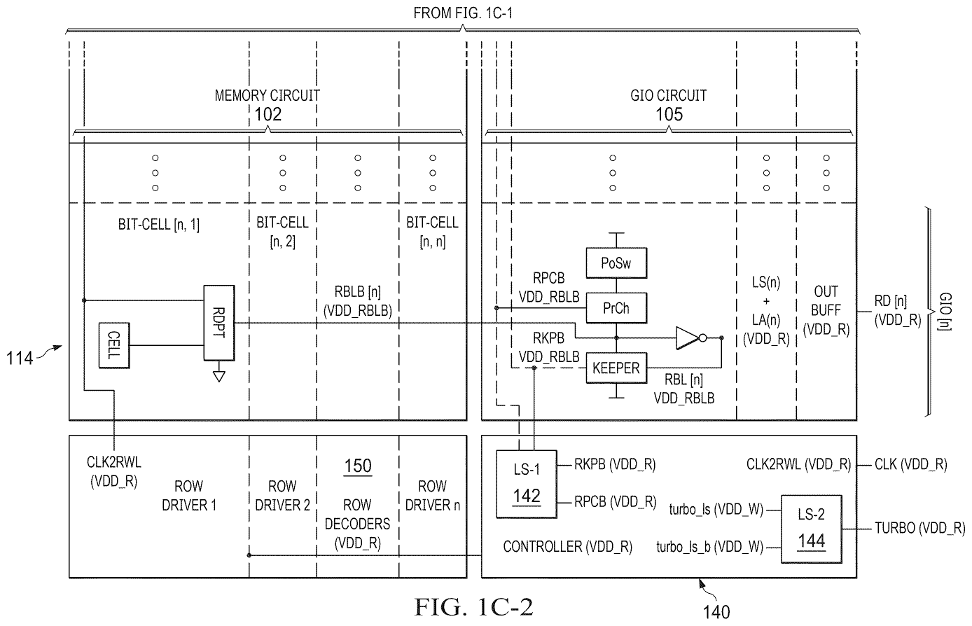

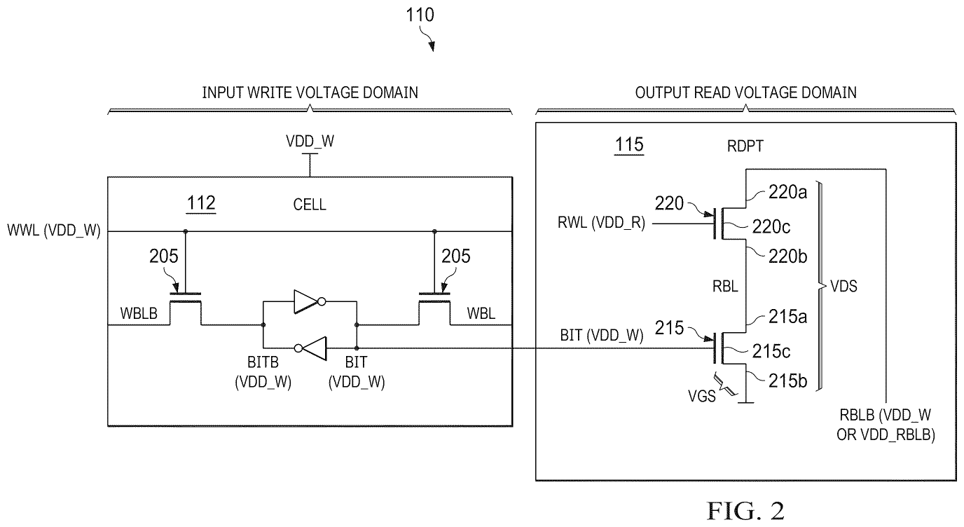

FIGS. 1A-1 and 1A-2 present a schematic block diagram of an example embodiment of an electrical device having a memory circuit and general input output circuit of the disclosure;

FIGS. 1B-1 and 1B-2 present a schematic block diagram of another example embodiment of an electrical device analogous, to the device shown in FIGS. 1A-1-1A-2;

FIGS. 1C-1 and 1C-2 present a schematic block diagram of another example embodiment of an electrical device analogous to the device shown in FIGS. 1B-1-1B-2;

FIG. 2 presents an example circuit diagram of a memory bit-cell of the memory circuit;

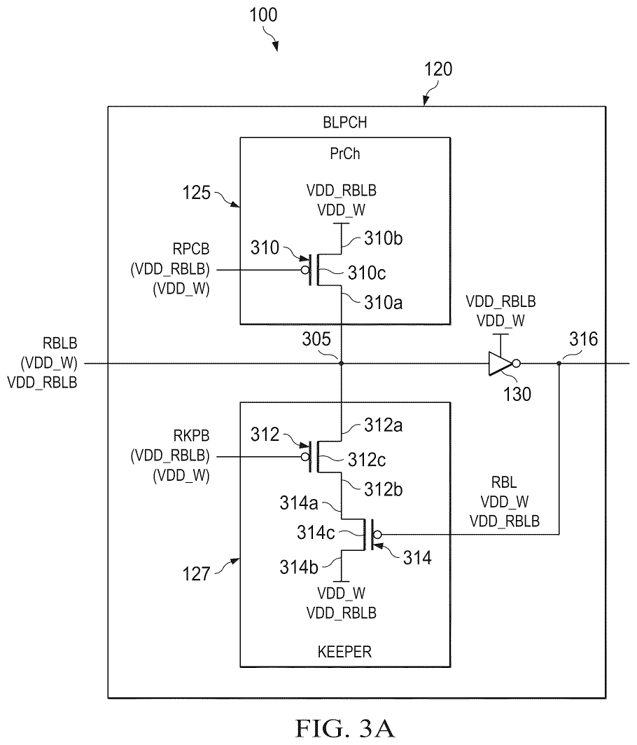

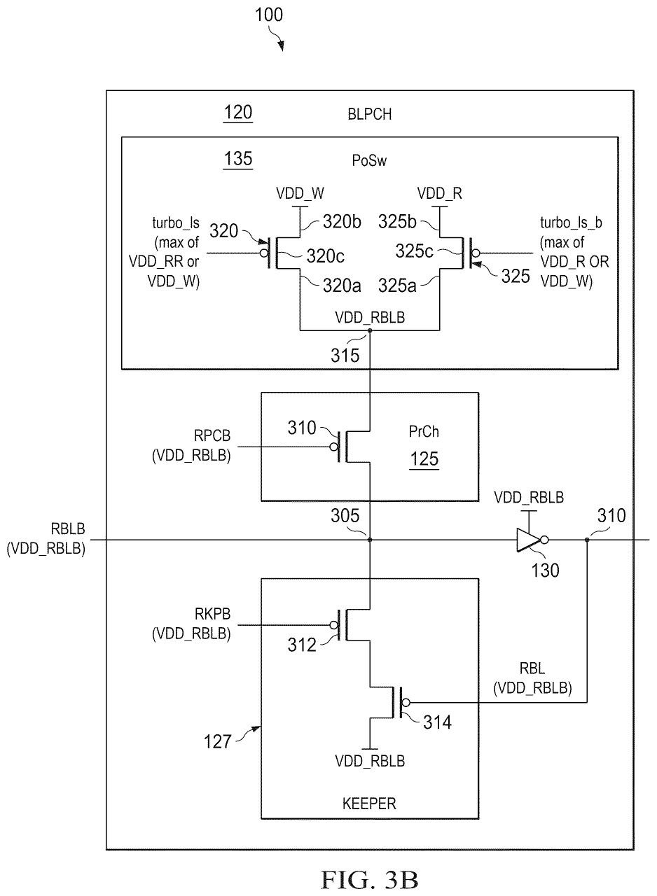

FIG. 3A presents an example circuit diagram of an example embodiment of a bit-line pre-charge control circuit of the general input output circuit of the disclosure;

FIG. 3B presents an example circuit diagram of another example embodiment of the bit-line pre-charge control circuit analogous to that shown in FIG. 3A; and

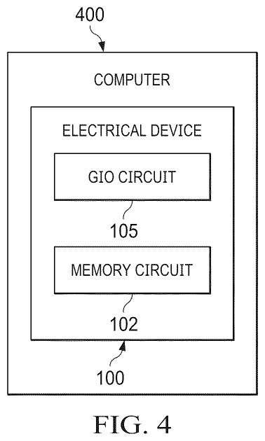

FIG. 4 presents a block diagram of a computer having one or more electrical circuits that include any embodiments of the electrical device such as disclosed in the context of FIGS. 1A-1-3B.

### DETAILED DESCRIPTION

As part of the present invention, we recognized several trade-off between frequency performance and the voltage domains involved when using voltage level shifters integrated into bit-cells, in particular, when reading from a bit-cell with a read voltage when it is at its maximum (e.g., typically 1.5 to 1.35 V) which is higher than a write voltage when it is at its minimum (e.g., typically 0.5 to 0.35 V).

As further disclosed below, we discovered that under such conditions, a memory bit-cell's performance suffers because of a wide voltage difference between two power domains occurring at the conjunction between two stacked n-channel metal-oxide semiconductor (NMOS) transistors of a conventional read port circuit of the bit-cell. Poor performance manifests as extremely long discharge rates, e.g., 2 to 6 times longer than an expected discharge rate. Consequently, as further disclosed below, the functional operating frequency of an entire memory cell array can become rate-limited by the slow-discharging bit-cell.

FIGS. 1A-1 and 1C-2 present schematic block diagrams various example embodiments of an electrical device 100 including a memory circuit 102 and general input output (GIO) circuit 105 of the disclosure, FIG. 2 presents a circuit diagram of an example memory bit-cell circuit of the memory circuit 102, and, FIGS. 3A-3B present circuit diagrams of example bit-line pre-charge control circuits of the GIO circuit 105.

With continuing reference to FIGS. 1A-1-3C throughout, embodiments of the memory circuit 102 can include a memory cell array 107 having a plurality of the bit-cell circuits (e.g., bit-cell 110). The GIO circuit 105 can include an array 112 of GIO circuits (GIO(1), GIO(s) . . . GIO(n) for each row of bit-cells (e.g., rows 114). Each bit-cell 110 includes transistors arranged to form a digital memory storage unit, a memory-cell (e.g., cell 112). For each bit-cell 110, the memory cell 112 is electrically connected to a read word line (RWL) and the cell 112 is electrically connected to a read-port circuit (Rdpt, 115) of the bit-cell by the RWL, e.g., to activate read access to the digital data (e.g., charge states corresponding to “1” or “0” data in bit storage node, “bit” or “bitb”, FIG. 2) stored in the memory-cell. As illustrated in FIGS. 1A-1-1C-2, the read-port circuit 115 is connected to the RWL, and to a read bit-line complement (RBLB). The read bit-line complement line (RBLB) is connected to a bit-line pre-charge control circuit 120 of the GIO circuit 105.

Any electrical connection lines between any such circuit components to carry such electrical signal can be carried by metal or other electrically conductive tracks, as familiar to those skilled in the pertinent art.

In accordance with the present invention, the read bit-line complement line (RBLB) carries a write output logic voltage (VDD_W) or a read bit-line complement output voltage (VDD_RBLB) that is less or equal to a conventional read output voltage (VDD_R; that is VDD_W or VDD_RBLB≤VDD_R). The advantages of the improved performance features associated such a connection architecture, are further disclose in the context of the example bit-cell circuit 110 of the memory circuit 102 embodiment depicted in FIG. 2.

As illustrated in FIG. 2, the bit-cell circuit 110 can include or be a six (6T) or eight (8T) or similar transistor circuit (e.g., generally transistors 205; dual port RAM; static random access memory, SRAM circuits, including 4T, 5T, 7T, 9T, and 10T memory cells) connected to the read port circuit 115, as shown in FIGS. 1A-1-1C-2. In some embodiments the memory cell can be a 6T SRAM, and together with the read port, form a 8T bitcell. Further abbreviations as shown in FIG. 2 are as follows: VDD_R, output read logic voltage, WWL, write word line; wbl, word bit-line; wblb, word bit-line complement; RWL, read word line; RBL, read bit-line; RBLB read bit-line complement; VGS, voltage difference across gate-to-source of a first N-type metal-oxide-semiconductor transistor 215 (e.g., source 215a, gate 215c, NMOS transistor 215) of the read port circuit 115; VDS, drain-to-source voltage difference between the drain of the first NMOS transistor 215 (e.g., drain 215c, NMOS transistor 215) and a source of a second NMOS transistor of the voltage level shifter circuit 220 (e.g., source 220a, NMOS transistor 220).

Conventionally, the memory cell 112 is considered to be in an input write voltage domain (e.g., VDD_W or VDD_RBLB equal to 0.35 to 0.5 V) and the read-port circuit 115 is considered to be in a separate output read voltage domain (e.g., VDD_R equal to 1.35 to 1.5 V). For such a conventional configuration, however, a large voltage level shift, and hence large voltage difference, can be presented at the conjunction in the read stack of NMOS transistors in the read port circuit 115 (e.g., first NMOS transistor 215 in write voltage domain of 0.35 or 0.5 V and second NMOS transistor 220 in the read voltage domain of 1.35 or 1.5 V). E.g., VDS can equal 1.35, 1.5 or 1.65 V, while the voltage gate-to-source voltage difference of a first N-type metal-oxide-semiconductor transistor will be at a minimum voltage (e.g., VGS equal to 0.35 or 0.5 V). The consequent higher resistance across the first NMOS transistor 215 compared to the second NMOS transistor 220 (e.g., a 2, 5, or 10 times higher resistance in some embodiments) can cause a longer time to discharge the read port associated with such a bit-cell. Substantially then, under such conditions, the read port's read frequency is dependent on the write voltage domain value. Consider, e.g., a margin check rule, where the discharge rate (slew rate) of a read bit-line (RBL or RBLB), must reach a trip point equal to 20% of the storage node charge, before a read word line (RWL) operation can be commenced. If the discharge rate the read port is lengthened by 300% (e.g., not reaching 20% until 2, 3, 4 or more times greater than an acceptable discharge time to 20% of 100, 60, 50 ps or less) then time before a RWL operation can occur is increased, and therefore the frequency rate of read word line operations is decrease accordingly.

The degraded discharge performance of such bit-cells can become rate-limiting for the logic data modulation rate of the entire macro-level memory cell array 107. Such degraded discharge performance can be exacerbated when considering transistor-to-transistor variations falling within the scope of a six-sigma variation acceptance of a foundry's process for manufacturing such bit-cells, or when considering increasing numbers of rows of bit-cells per bit-line for larger memory arrays (e.g., arrays with 25×10⁶ bit-cells, 25 MB, or larger).

One possible strategy to mitigate such degraded performance would be to consider increasing the size of the first NMOS transistors 215 (e.g., increasing from a one to a two, three or four fin field effect transistor). However, such a change would require a substantial redesign of the circuit, and that redesign would have to be implemented at the memory circuit fabrication foundry, which would be time consuming and expensive. Other possible strategies to mitigate such degraded performance may be to consider changing the threshold voltage (Vt) of the NMOS transistors, slowing the clock cycle rate (e.g., to allow the read bit-line to fall to 20%) or to subdivide the read bit-line row of the macro memory circuit into multiple smaller bit-cell segments (e.g., from a 128 or a 64 bit-cell row-length to 8 or 4 16 bit-cell row-lengths, respectively). But, again, such changes would require time consuming and expensive foundry-level redesigns of the memory circuit and, in some cases, may result in an undesirably larger and/or slower circuit e.g., due to increased total resistance and capacitance across the rows and the additional receivers needed to read each subdivided row length segments.

As part of the present disclosure, we have changed the bit-line pre-charge connection pathway architecture to pre-charge port using a voltage equal to the input write voltage domain (VDD_W or VDD_RBLB), and further change the device architecture change so that voltage level shifting is performed in the GIO circuit. Pre-charging in the VDD_W or VDD_RBLB domain avoids direct dependency on the VDD_R domain for the bit-line pre-charge operation. This helps to eliminate the degraded discharge performance of the NMOS transistor 215 in the read port circuit 115 that was becoming rate-limiting.

As shown in FIGS. 1A-1-1C-2, the RBLB, at the lower voltage of VDD_W or VDD_RBLB, can be connected to and pre-charge the second NMOS transistor 220 of the read port circuit 115. Consequently, the second NMOS transistor 220 will be at about the same voltage as the first NMOS 215 which is at a bit node signal line (bit, bitb) of VDD_W. As a result, the discharge rate across the read stack of NMOS transistors 215, 220 is not degraded because the VDS between these two transistors 215, 220, of each bit-cell read port circuit of a memory array 107, will be substantially zero (e.g., 0.15, 0.1 V or less or 0.0 V±0.15 V or ±0.1 V Or ±0.05 in some embodiments), or at least, not as large as when the bit-line is pre-charged with a voltage in the output read voltage domain (VDD_R).

This disclosed change in pre-charger connection architecture can provide several previously unrecognized advantages. By pre-charging the bit-line in the VDD_W domain, direct dependency on the VDD_R domain for the bit-line pre-charging is eliminated. Performing voltage level shifting in the GIO circuit rather than at the bit-cell also simplifies the memory circuit's design and reduces slew rate degradation in the read port circuit 115. Performing voltage level shifting in the GIO also enables designers the flexibility to optimize transistor device sizes and Vt to improve performance, as compared to when the bit-cell itself is configured had to handle the voltage level shifting, where device sizing is not available. Importantly, we are selectively changing a bit-line pre-charge level from VDD_R to VDD_W domain, e.g., there is no voltage change from a clock to RWL path, which remain in its VDD_R voltage domain.

Keeping the pre-charge operation within the VDD_W domain can isolate the read port circuit from VDD_R variations, and thereby lead to more stable and predictable pre-charge behavior, especially under varying voltage operating conditions. Eliminating the bit-line discharge and pre-charge stage from the frequency-critical path can lead to improved overall frequency performance of the macro memory circuit. Because pre-charging the bit-line in the VDD_W domain decouples the read port's from the higher voltage domain's (VDD_R) speed expectations for read operations. E.g., whenever VDD_R goes high, the clock and macro memory circuit can be operated at higher frequencies, accordingly.

Returning to FIGS. 1A-1-1C-2, one embodiment of the disclosure is an electrical device 100 including a memory circuit 102 and general input output (GIO) circuit 105.

The memory circuit 102 includes bit-cell circuits 110, each bit-cell circuit including a memory cell 112 (Cell) and a read port 115 (Rdpt). The memory cell can be electrically connected to a read word line at a read output voltage (RWL, (VDD_R)) and can be electrically connected to the read port 115 by the read word line (RWL). The read port 115 can be further connected to a read bit-line complement signal (RBLB) at a write output logic voltage (FIG. 1A-1-1A-2, RBLB (VDD_W)) or at a read bit-line complement output voltage (FIG. 1B-1-1B-2 or 1C-1-1C-2, RBLB (VDD_RBLB)) that can be less than or equal to the write output logic voltage (VDD_W). The general input output (GIO) circuit 105 including a bit-line pre-charge control circuit 120 and a voltage level shifter circuit (LS) wherein the read bit-line complement signal RBLB can be connected to the bit-line pre-charge control circuit 120 and to the voltage level shifter circuit (LS).

Turning to FIG. 2, the read port 115 (Rdpt) includes an in-series stack of first and second NMOS transistors 215, 220.

As also illustrated in FIG. 2, the memory cell 112 (Cell) includes a bit node signal (bit, bitb) at the write output logic voltage (VDD_W) and the bit node signal can be connected to a gate 215c of the first NMOS transistor 215.

As further illustrated in FIG. 2, the read word line (RWL) at the read output voltage (VDD_R) can be connected to a gate 220c of the second NMOS transistor 220 and the read bit-line complement signal RBLB at the write output logic voltage (VDD_W) or at the read bit-line complement output voltage (VDD_RBLB can be connected to a drain 220b of the second NMOS transistor 220. In some such embodiments, the read word line (RWL) is part of a clock-to-read word line signal pathway (CLK2RWL) at the read output voltage (VDD_R).

For instance, as shown in FIGS. 1A-1-1C-2, the clock-to-read word line signal pathway (CLK2RWL) can be a general clock signal (CLK) transmitted to a controller circuit 140 of the device, and which in turn is transmitted to the read word line (RWL) of the memory circuit 102. By keeping the clock-to-read word line signal pathway in the VDD_R domain and just changing the bit-line voltage domain to VDD_W domain and then, level shifting in GIO array 111, allows the cells 110 of the memory cell array 107 to operate faster, by avoid the long discharge rates as discloses elsewhere herein.

In some embodiments of the device 100, a voltage difference (VDS, FIG. 2) between a drain 215a of the first NMOS transistor 215 and a source 220b of the second NMOS transistor 220 can be less than ±0.15 V, or less than ±0.1 V or less than, ±0.05 V.

Returning to FIGS. 1A-1-C-2, in some embodiments, the GIO circuit 105 includes an array 112 of the GIO circuits GIO(1), GIO(s) . . . GIO(n), the bit-cell circuits can be connected in rows 114 and each of the rows of bit-cells can be connected to different ones of the GIO circuits in the array of GIO circuits 112.

In some embodiments, each of the GIO circuits (GIO(1) . . . GIO(n)) in the array of GIO circuits 112 can include separate ones of the bit-line pre-charge control circuit 120 and the voltage level shifter circuits (LS(1) . . . LS(n)) connected to separate ones of latch circuits connected thereto (LA(1) . . . LA(n)).

In some embodiments, the voltage level shifter circuits (LS) and the latch circuits (LA) can carry the read output voltage (VDD_R). In some such embodiments, the bit-line pre-charge control circuits 120 can carry the write output logic voltage (VDD_W) or read bit-line complement voltage (VDD_RBLB).

As illustrated in FIGS. 1A-1-1C-2 and 3A in some embodiments, the bit-line pre-charge control circuit 120 can include a pre-charge circuit 125 (PrCh), a keeper circuit 127 (Keeper) and an inverter circuit 130. The pre-charge circuit 125, the keeper circuit 127 and the inverter circuit 130 can be connected to the read bit-line complement signal RBLB at a common node point 305.

In some such embodiments, the pre-charge circuit 125 (PrCh) can include a P-channel Metal-Oxide-Semiconductor (PMOS) transistor 310 having a drain 310a connected to the common node point 305, a source 310b at the write output logic voltage (VDD_W) or the read bit-line complement output voltage (VDD_RBLB), and a gate 310c connected to receive a read pre-charge complement signal, (RPCB) at the write output logic voltage (VDD_W) or at the read bit-line complement output voltage (VDD_RBLB).

In some such embodiments, the pre-charge circuit 125 (PrCh) can include a PMOS transistor 310 having a drain 310a connected to the common node point 305, a source 310b at the write output logic voltage (VDD_W) or the read bit-line complement output voltage (VDD_RBLB), and a gate 310c connected to receive a read pre-charge complement signal, (RPCB) at the write output logic voltage (VDD_W) or at the read bit-line complement output voltage (VDD_RBLB).

In some such embodiments, the keeper circuit 127 can include a first PMOS transistor 312 having a drain 312b connected to the common node point 305, and a gate 312c connected to receive a read keeper complement signal (RKPB) at the write output logic voltage (VDD_W) or at the read bit-line complement output voltage (VDD_RBLB), and a source 312a of the first PMOS transistor 312 connected to a drain 314b of a second PMOS transistor 314 of the keeper circuit. A source 314a of the second transistor 314 can be at the write output logic voltage (VDD_W) or the read bit-line complement output voltage (VDD_RBLB). A gate 314c of the second PMOS transistor 314 can be connected at a second common node point 316 to connect a read bit-line signal (RBL), at the write output logic voltage (VDD_W) or at the read bit-line complement output voltage (VDD_RBLB), to the voltage level shifter circuit (LS).

In some such embodiments, the pre-charge circuit 125, the keeper circuit 127 and the inverter circuit 130 of the pre-charge control circuit 120 can be operably connected to work together to avoid race conditions by having a specific timing relationship between the RWL, RPCB and RKPB signals.

In the disclosure to follow, the following abbreviations apply: read bit-line pre-charge off before RWL on, R2L; read bit-line pre-charge on after RWL off, R3L; read bit-line discharge before RWL fall, R4L. A R2L race condition can occur on the leading edge of the clock. We ensure that RPCB goes high (e.g., 50% of pre-charge level of bit-line level) before RWL go high (e.g., 50% of VDD_R). A R3L race condition can occur on the trailing edge of the clock. We ensure RWL falls (e.g., 50% of VDD_R) before RPCB falls (e.g., 50% of pre-charge level of bit-line level. Concerning a R4L race conditions, we ensure the read bit-line discharges (to 20% of pre-charge level of bit-line) before RWL falls (80% of VDD_R).

Both the read pre-charge complement (RPCB) signal and the read word line (RWL) signal can be generated through a main clock (CLK) signal, but a delay to generate both signals can be different based on these race conditions. That is, for such memory circuit designs, both the RPCB and the RWL signals can be derived from the main CLK signal, but, their generation can involve different delay paths due to the timing requirements for pre-charge and read operations.

Regarding the timing relationships between the RPCB and the RWL signals, in sequential operations, RPCB controls the pre-charge operation of bit-lines, preparing the memory cell 112 for the next read or write cycle. The RPCB signal is properly timed so that the pre-charge operation completes before activating the RWL signal. The RWL signal activates the word line of a memory cell row 114, enabling access to the data stored in the memory cells of that row. The RWL signal can be asserted after the bit-lines are pre-charged.

Further, regarding the timing relationships between the RPCB and the RWL signals, as noted, there can be clock-driven delay differences. Both signals can be generated based on the rising or falling edge of the CLK signal in phase, based circuit design and being controlled through an internally generated CLK signal in a self-timed design, but with intentional delays to meet the design's timing constraints. E.g., the delay for generating the RPCB signal is generally shorter than the delay for generating the RWL signal to help ensure that pre-charging is completed before RWL activates a row. The race condition between the RPCB and RWL signal delays is important to control. E.g., the RWL signal activates too early, before RPCB has fully pre-charged the bit-lines then this can lead to data corruption or other signal integrity issues.

Regarding the management of race conditions, a circuit design can include added delay buffers or timing control circuits to ensure that the RPCB signal deactivates (e.g., completing the pre-charge operation) before the RWL signal is asserted. This time sequencing helps prevent premature access to the memory cell row. The delay difference between the RPCB and RWL can be tuned during the design's timing analysis, factoring in variations in temperature, voltage, and process corners to avoid potential race conditions across operating conditions.

Regarding the timing relationships between the RPCB and the RWL signals, and its impact on circuit and stability and performance, properly managing the delay relationship between the RPCB and the RWL signals is important to achieve both data stability and fast access times. Optimizing the delays and their differences allows for higher memory speeds without sacrificing reliability.

Thus, while the timing relationships between the RPCB and the RWL signals, can be clock-driven, it is important for their individual delay paths to be adjusted to prevent race conditions, and ensure that pre-charge (via the RPCB signal) completes before row access (via the RWL signal) begins. The timing coordination between the RPCB and the RWL signals is an important element of stable and high-performance memory operation.

Regarding the timing relationships between the RPCB and the RKPB signals, having precise timing coordination, is important when using the keeper circuit 117 (keeper). The keeper circuit helps maintain the bit-line voltage during a read operation, and when managed dynamically (e.g., activated by the RKPB signal), can enhance performance while maintaining data integrity. The timing relationship between the RBLB and RKPB signals consider two important timing margins: an evaluation margin and a leaker margin.

The purpose of the evaluation margin is to ensure accurate signal evaluation conditions of the RBLB signal. For instance, the dynamically managed keeper (via the RKPB signal) can be delayed until RBLB signal discharges to, e.g., at least 20% of a read bit-line pre-charge signal level, to allow sufficient voltage drop on the RBLB signal and thereby, ensure that the bit-line accurately reflects, e.g., a logical “0” when a “0” is read. For instance, if the keeper were to activate too early, it could interfere with the discharge, pulling the bit-line back up and causing an incorrect read, particularly when reading a low signal (e.g., a discharge signal). Waiting until the RBLB signal has discharged to 20% helps achieve a robust read margin, allowing a sense amplifier to detect the data correctly.

The purpose of the leaker margin is to prevent excessive charge leakage conditions from RBLB signal and thereby ensure data integrity during a read cycle. That is the keeper (via the RKPB signal) is activated before the charge on RBLB signal leaks away significantly (e.g., 20% in some embodiments), which could lead to an incorrect read operation. During the read operation, bit-lines are prone to slow charge leakage. If the keeper is delayed too much, this charge could drain away, especially when holding a high level (e.g., pre-charged), leading to potential read errors due to signal degradation. Activating the RKPB signal before significant leakage occurs ensures that the RBLB signal voltage is maintained and that the sense amplifier detects the correct logical value.

Regarding the timing coordination between the RPCB and the RKPB signals, important considerations include race conditions, timing adjustments, and environmental variations. The keeper's design balances the evaluation margins and the leaker margins to avoid race conditions. That is, the keeper circuit timing (controlled by the RKPB signal) is delayed to meet both the evaluation and leaker margins. The keeper circuit's design can include introduced delay buffers or dynamic timing control circuits to tune the RKPB signal timing against the RBLB signal timing to help meet both the evaluation and leaker margins, and thereby allow the RBLB signal to discharge sufficiently before the keeper turns on, while still maintaining RBLB signal's charge integrity. These timing margins are adjusted to be met across process, voltage, and temperature (PVT) variations to ensure consistent read accuracy under diverse environment operating conditions. Thus the dynamic keeper timing scheme (via the RKPB signal) helps stabilize RBLB signal by preventing signal degradation, the relative timing of RKPB and RBLB by balancing the evaluation and leaker margins, where the evaluation margin has a delay in the RKPB signal activation to allow RBLB signal to discharge, and the larger margin has a timely activation to maintain the charge.

As illustrated in FIGS. 1C-1-1C-2 and 3B, in some such embodiments, the bit-line pre-charge control circuit 120 can includes a power switch circuit 135 (PoSw) connected to the pre-charge circuit 125 at a common node point 315 at the read bit-line complement output voltage (VDD_RBLB). In some such embodiments, the power switch control circuit 135 can include a first PMOS transistor 320 and a second PMOS transistor 325 that are parallel-connected to each other at the common node point 313 by a source 320a of the first PMOS transistor 320 and a source 325a of the second transistor 325.

As also illustrated in FIGS. 1C-1-1C-2 and 3B, in some embodiments, a source 320b of the first PMOS transistor 320 can be at the write output logic voltage (VDD_W), a source 325b of the second PMOS transistor 325 can be at the read output voltage (VDD_R), a gate 320c of the first PMOS transistor 320 can be connected to a voltage level shifted turbo signal at a maximum of the write output logic voltage or the read output voltage (turbo_ls, max of VDD_R or VDD_W) and a gate 325c of the second PMOS transistor 325 can be connected to a complement voltage level shifted turbo signal at the maximum of the write output logic voltage or the read output voltage (turbo_ls_b, max of VDD_R or VDD_W).

As shown in FIGS. 1A-1-1C-2, embodiments of the device 100 can further include a control circuit 140 (Controller) connected to receive a main clock signal at the read output voltage (CLK (VDD_R)) and connected to receive a turbo signal at the read output voltage (TURBO (VDD_R)). The main clock signal can be generated by a clock generator of the circuit 100 as familiar to those skilled in the pertinent art

The term turbo signal, as used herein, refers to an elevated voltage signal to enhance performance by temporarily increasing the speed or bandwidth of a circuit, often at the expense of higher power consumption or reduced reliability over time. The turbo signal can be generated by a power management unit of the circuit 100 as familiar to those skilled in the pertinent art, using a turbo pin, that when activated by a voltage, allows adjustment of the frequency based on state of the pin, e.g., when the state of the turbo pin equals 0 at lower voltage and equals 1 at higher voltage E.g., when VDD_W<0.7 V the turbo pin signal will be tied to the lower voltage and pre-charging of the read bit-line (RBL) in the VDD_W domain will occur. E.g., when VDD_W>0.7 V then the turbo pin signal will be tied to the higher voltage and pre-charging of the read bit-line (RBL) in VDD_R domain will occur. This can advantageously allow adaptive optimization of the balance between performance and power consumption.

In some such embodiments, the control circuit 140 can include a first voltage level shifter 142 (LS-1) connected to receive a read pre-charge complement signal (RPCB) at the read output voltage (VDD_R) and a read keeper complement signal (RKPB) at the read output voltage (VDD_R) and transmit the read keeper complement signal and the read pre-charge complement signal at the write output logic voltage (VDD_W) or the read bit-line complement output voltage (VDD_RBLB) to the bit-line pre-charge circuit 120 of the general input output (GIO) circuit 105. For example, as discussed above in the context of FIG. 3A, the RPCB signal from the first voltage level shifter 142 (LS-1) can be connected to the PMOS transistor 310 of the pre-charge control circuit 125, and the RKPB signal from the from the first voltage level shifter 142 (LS-1) can be connected to the first PMOS transistor 312 of the keeper circuit 127.

As illustrated in FIG. 3B, in some such embodiments, the controller can further include a second voltage level shifter 144 (LS-2) to receive the turbo signal at the read output voltage (TURBO (VDD_R)) and transmit a voltage level shifted turbo signal (turbo_ls) and a complement voltage level shifted turbo signal (turbo_ls_b) at a maximum of the write output logic voltage (VDD_W) or of the read output voltage (VDD_R).

For example, the turbo signal at the read output voltage and its complement (generally, “turbo”) can be voltage level shifted to produce a voltage level shifted turbo signal and complement voltage level shifted turbo signal (turbo_ls and turbo_ls_b, respectively).

For example, as discussed elsewhere herein, in the context of FIG. 3B, in some embodiments, the turbo signal can be received by a voltage level shifter of the control circuit (e.g., second voltage level shifter, LS-2) and be converted to the voltage level shifted turbo signal (turbo_ls) and the complement voltage level shifted turbo signal (turbo_ls_b) that are then transmitted to the gates 320c 325c of the first and second PMOS transistors 320, 325 of the power switch circuit 135.

As also shown in FIGS. 1A-1-1C-2, embodiments of the device 100 can further include a row decoder circuit 150 (Row Decoder) connected to carry signals at the read output voltage (VDD_R) to and from the control circuit 140 and carry signal to and from the memory circuit 102 at the read output voltage (VDD_R).

As illustrated in FIG. 4, any of the disclosed embodiments of the electrical device 100 with the memory circuit 102 and the general input output (GIO) circuit 105 can be part of a computer 400.

Those skilled in the art to which this application relates will appreciate that other and further additions, deletions, substitutions and modifications may be made to the described embodiments.

What is claimed is:

1. An electrical device, comprising:
a memory circuit including bit-cell circuits, each bit-cell circuit including a memory cell and a read port, wherein:
the memory cell is electrically connected to a read word line at a read output voltage and is electrically connected to the read port by the read word line, and
the read port is further connected to a read bit-line complement signal at a write output logic voltage or at a read bit-line complement output voltage that is less than or equal to the write output logic voltage; and
a general input output circuit including a bit-line pre-charge control circuit and a voltage level shifter circuit, wherein the read bit-line complement signal is connected to the bit-line pre-charge control circuit and to the voltage level shifter circuit.

2. The device of claim 1, wherein the read port includes an in-series stack of first and second NMOS transistors.

3. The device of claim 1, wherein the memory cell includes a bit node signal at the write output logic voltage and the bit node signal is connected to a gate of the first NMOS transistor.

4. The device of claim 1, wherein the read word line at the read output voltage is connected to a gate of the second NMOS transistor and the read bit-line complement signal at the write output logic voltage or at the read bit-line complement output voltage is connected to a drain of the second NMOS transistor.

5. The device of claim 4, wherein the read word line is part of a clock-to-read word line signal pathway at the read output voltage.

6. The device of claim 1, wherein a voltage difference between a drain of the first NMOS transistor and a source of the second NMOS transistor is less than ±0.15 V.

7. The device of claim 1, wherein the general input output circuit includes an array of the general input output circuits, the bit-cell circuits are connected in rows and each of the rows of bit-cells are connected to different ones of the general input output circuits in the array of general input output circuits.

8. The device of claim 1, wherein each of the general input output circuits in the array of general input output circuits include separate ones of the bit-line pre-charge control circuit and the voltage level shifter circuits connected to separate ones of latch circuits connected thereto.

9. The device of claim 1, wherein the voltage level shifter circuits and the latch circuits carry the read output voltage.

10. The device of claim 9, wherein the bit-line pre-charge control circuits carries the write output logic voltage or read bit-line complement voltage.

11. The device of claim 1, wherein the bit-line pre-charge control circuit includes a pre-charge circuit, a keeper circuit and an inverter circuit, wherein the pre-charge circuit, the keeper circuit and the inverter circuit are connected to the read bit-line complement signal at a common node point.

12. The device of claim 11, wherein the pre-charge circuit includes a PMOS transistor having a drain connected to the common node point, a source is at the write output logic voltage or the read bit-line complement output voltage, and a gate connected to receive a read pre-charge complement signal at the write output logic voltage or at the read bit-line complement output voltage.

13. The device of claim 11, wherein:
the keeper circuit includes a first PMOS transistor having a drain connected to the common node point, and a gate connected to receive a read keeper complement signal at the write output logic voltage or at the read bit-line complement output voltage, and a source of the first PMOS transistor connected to a drain of a second PMOS transistor of the keeper circuit,
a source of the second PMOS transistor is at the write output logic voltage or the read bit-line complement output voltage,
a gate of the second PMOS transistor connected at a second common node point to connect a read bit-line signal, at the write output logic voltage or at the read bit-line complement output voltage, to the voltage level shifter circuit.

14. The device of claim 12, wherein the bit-line pre-charge control circuit includes a power switch circuit connected to the pre-charge circuit at a common node point at the read bit-line complement output voltage.

15. The device of claim 14, wherein the power switch control circuit includes a first PMOS transistor and a second PMOS transistor that are parallel-connected to each other at the common node point by a source of the first PMOS transistor and a source of the second transistor.

16. The device of claim 15, wherein a source of the first PMOS transistor is at the write output logic voltage, a source of the second PMOS transistor is at the read output voltage, a gate of the first PMOS transistor is connected to a voltage level shifted turbo signal at a maximum of the write output logic voltage or the read output voltage and a gate of the second PMOS transistor is connected to a complement voltage level shifted turbo signal at the maximum of the write output logic voltage or the read output voltage.

17. The device of claim 1, further including a control circuit 140 connected to receive a main clock signal at the read output voltage and connected to receive a turbo signal at the read output voltage.

18. The device of claim 17, wherein the control circuit includes a first voltage level shifter connected to receive a read pre-charge complement signal at the read output voltage and a read keeper complement signal at the read output voltage and transmit the read keeper complement signal and the read pre-charge complement signal at the write output logic voltage or the read bit-line complement output voltage to the bit-line pre-charge circuit of the general input output circuit.

19. The device of claim 17, wherein the controller further includes a second voltage level shifter to receive the turbo signal at the read output voltage and transmit a voltage level shifted turbo signal and a complement voltage level shifted turbo signal at a maximum of the write output logic voltage or of the read output voltage.

20. The device of claim 17, further including a row decoder circuit connected to carry signals at the read output voltage to and from the control circuit and carry signal to and from the memory circuit at the read output voltage.

21. The device of claim 1, wherein the electrical device with the memory circuit and the general input output circuit are part of a computer.
